(19) United States
(12) Patent Application Publication
(10) Pub. No.: US 2005/0012434 A1
(43) Pub. Date: Jan. 20, 2005

(54) Robust piezoelectric power generation module

(75) Inventors: Alessandro Pizzochero, Chelmsford, MA (US); Nesbitt W. Hagood IV, Wellesley, MA (US)

Correspondence Address: HAMILTON, BROOK, SMITH & REYNOLDS, P.C., 530 VIRGINIA ROAD, P.O. BOX 9133, CONCORD, MA, 01742-9133, US

(73) Assignee: Continuum Photonics, Inc., Billerica, MA (US)

(21) Appl. No.: 10/811,300

(22) Filed: Mar. 26, 2004

Related U.S. Application Data
(60) Provisional application No. 60/458,034, filed on Mar. 26, 2003.
(60) Provisional application No. 60/458,544, filed on Mar. 27, 2003.

(51) Int. Cl. H01L 41/113

(52) U.S. Cl. 310/339

(57) ABSTRACT

An electrical power generation system includes a transducer that generates electrical energy under dynamic mechanical loading. A buffer is mechanically coupled to the transducer and adapted to be mechanically coupled to a structure. The buffer facilitates the transducer to operate within a predetermined mechanical loading range to allow the system to provide electrical energy. An electricity generator module includes a transducer that generates electrical energy under dynamic motion conditions. A circuit coupled to the electrically transducer converts the electrical energy into usable electricity at a circuit output. A planar housing encloses the transducer and circuit and (i) allows the transducer to be exposed to the dynamic motion conditions and (ii) provides electrical contacts that facilitate delivery of the useable electricity for external circuitry.

### RELATED APPLICATIONS

This application claims the benefit of U.S. Provisional Application No. 60/458,034, filed on Mar. 26, 2003, and U.S. Provisional Application No. 60/458,544, filed on Mar. 27, 2003. The entire teachings of the above applications are incorporated herein by reference.

### BACKGROUND OF THE INVENTION

Solid state transducers, such as piezoelectric or electrostrictive materials, may be used for mechanical-to-electrical energy conversion in applications involving high-bandwidth or cyclic tasks of large deflection or strain structures. Collection of the electrical energy is generally referred to as “energy harvesting.” In such applications, the transducer material is bonded or attached to the structure from which it is to harvest energy. However, general purpose transducers for energy harvesting applications are not commonly available, and typically a person wishing to implement such a power-generation task takes raw, possibly non-electroded, transducer material stock, together with any necessary electrodes, adhesives, and insulating structures, and proceeds to fasten it onto, or incorporate it into the structure of interest.

For such applications, it becomes necessary to connect and attach these materials in such a way that the mechanical and electrical connections to the transducer are robust and capable of transferring appropriate strain to the transducer member, and to couple the strain, motion or force from the structure that is supplying energy to the transducer. Often, it is required that the transducer material be used in a non-benign environment, greatly increasing the chances of its mechanical or electrical failure. Typical transducer materials are relatively fragile, typically weak in tension, and therefore subject to mechanical performance degradation when exposed to operational loads. This leads to partial or complete loss of the transducer's functionality.

One such application, that of harvesting energy from a base-structure undergoing large deflection or strain, requires attachment of a piezoelectric element (or multiple elements) to the structure. When these elements are then deformed/strained by the base-structure, the piezoelectric effect transforms mechanical energy applied to the elements into electrical energy that can then be processed by energy-harvesting electronics.

### SUMMARY OF THE INVENTION

The application of self-powered devices in high strain/deflection base-structures requires robust generator elements that can withstand the mechanical inputs and, possibly, adverse environments, while providing reliable energy supply. Solutions using active materials that operate on the piezoelectric and/or electrostrictive effect are limited by the material's inability to withstand high strains. Thus, improvements are desirable in the manner in which a generator element is bonded to a base-structure, such that the element may have high bandwidth performance capabilities and be easily set-up, yet be mechanically and electrically robust, while not significantly altering the mechanical properties of the base-structure as a whole.

One embodiment of the present invention defines an electrical power generation system including a transducer (e.g., an electro-active element having piezo-electric ceramic material) that generates electrical energy under dynamic mechanical loading, such as strain, stress, or bending conditions. A buffer is mechanically coupled to the transducer and adapted to be mechanically coupled to a structure. The buffer facilitates the transducer to operate within a predetermined mechanical loading range to allow the system to generate the electrical energy.

The buffer may be stiffer than a local stiffness of the structure. In this case, the buffer may include at least one of the following materials: composite, metal, fiber, or polymer. In an alternative embodiment, the buffer may be less stiff than a local stiffness of the structure. In this case, the buffer may include at least one of the following materials: rubber, foam, plastic, or composite.

The system may also include a second buffer coupled to the transducer separate from the other buffer. In one embodiment, the buffers form a seal around the transducer. The electrically conductive pattern may include contacts exposed external from the buffers forming the seal. In an alternative embodiment, one buffer surrounds the electro-active element. In either case, the buffer(s) may be laminar. Still further the buffer(s) may be surface bonded or attached to the structure.

The electrically conductive pattern may be disposed on a film in a layered relationship to the transducer. The transducer and the buffer may be in a layered relationship to each other.

The transducer may also include an energy harvesting circuit electrically coupled to the transducer and disposed in a layered relationship with the transducer. The circuit and transducer may be on the same layer or different layers.

Another embodiment according to the principles of the present invention defines an electricity generator module. The electricity generator module includes a transducer that generates electrical energy under dynamic motion conditions. A circuit in a layered coupled to the transducer converts the electrical energy into usable electricity at a circuit output. A planar housing encloses the transducer and circuit. The housing allows the transducer to be exposed to the dynamic motion conditions and provides electrical contacts coupled to the circuit output to facilitate delivery of the usable electricity to external circuitry.

The circuit in the electricity generator module may be an energy harvesting circuit powered by the electrical energy generated by the transducer. The dynamic motion conditions may include strain, and the buffer may be stiffer or softer than a local stiffness of the source of the dynamic motion conditions. The module may be manufactured by a lamination process. The module may be bonded or attached to a structure.

### BRIEF DESCRIPTION OF THE DRAWINGS

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

These and other desirable properties of the invention will be understood from the detailed description of illustrative embodiments, wherein:

FIG. 1 is an exploded and assembled view of the RPPGM module.

FIG. 2 is a representation of optimal operating performance of a typical transducer as a function of input strain.

FIG. 3 is a functional schematic of the RPPGM module with either a relatively soft or stiff buffer ply depending on the deflection magnitude and properties of the base-structure.

FIG. 4 is an exploded schematic view of an Active Fiber Composite and a wafer-based transducer device.

FIG. 5 illustrates how the RPPGM may be used in a general surface-mounted configuration.

FIG. 6 is an exploded functional view of an RPGM device and all constituent components including optional energy-harvesting module.

FIGS. 7a-7d show various uses of the transducer module.

FIG. 8 is an exploded view of an RPGM device including optional energy-harvesting surface mounted electronics.

FIG. 9 is an assembled RPGM prior to encapsulation and includes optional energy-harvesting electronics.

FIG. 10 is an RPGM with encapsulation and optional energy-harvesting electronics.

### DETAILED DESCRIPTION OF THE INVENTION

The principles of the present invention relate to a robust, packaged (optional), energy-harvesting module utilizing piezoelectric transducer materials to gather energy from motion of large-deflection base-structures. The module provides useable electricity that may be used to provide power for electric devices.

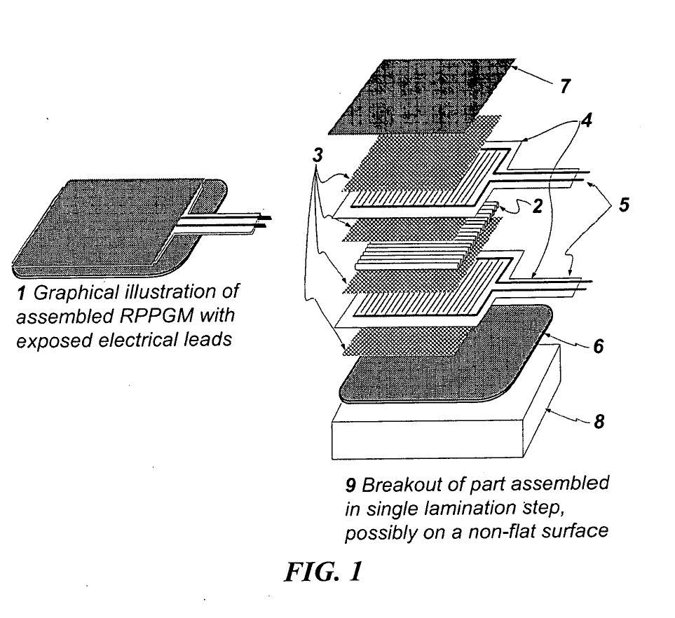

The active material element transducers may be the same or similar to those used for active vibration control, structural control, precision positioning, motion control, and passive or active damping. The transducer may be in laminar (i.e., layered) relationship with power-harvesting electronics and disposed together in or attached to high-strain structures, where mechanical strains are greater than material limits of the active material and/or vary significantly. A functional Robust Piezoelectric Power Generate Module (RPPGM) assembly has been developed for use in power generation for self-powered devices and is schematically represented in FIG. 1.

The RPPGM device 1 may include discrete components, optionally laminated and connected together with electrical interconnects where appropriate, typically via flexible circuits (“flex-circuits”) or wires. The main power generation source may be a laminar transducer element 2 that is bonded, attached, embedded in, or otherwise connected to the surface of a high strain (where strains are on the order of 0.1% or higher) or large motion/vibration base-structure 8. The transducer element 2 may be encapsulated with adhesive material 3 between one or two electrode plies 4 that contain two electrical leads 5 on a flex-circuit for interfacing with electronics. This laminar transducer sub-assembly may be encapsulated between one or two plies of buffer material 6. The overall package can be assembled with a lamination or other suitable process.

The packaged generator elements may be used to convert large mechanical motion in the form of vibration, cyclic or non-cyclic deflection, shaking, stirring, straining, or relative motion between two objects into electrical energy for use by other electrical load devices. As illustrated in FIG. 1, the robust packaged power-generator assembly 1 may include transducers 2, adhesives 3, electrodes 4 with power leads 5, structural buffer ply 6, and encapsulating materials 7 arranged in such a way as to optimally convert mechanical motion from the host base-structure 8 into mechanical energy without exceeding mechanical limits of the transducers, which are typically fragile transducer elements.

As described in more detail below, the assembly 1 may be bonded or attached to a base-structure or system, thereby integrating it with the system from which electrical energy is to be extracted. This mechanically robust generator can reliably operate in a base-structure's strain environment and provide energy for electronic devices

The Robust Piezoelectric Power Generation Module (RPPGM) assembly according to the principles of the present invention may include multiple power-generation transducer elements, such as a piezoelectric or electrostrictive plate, shell, ribbon, fibers, or composites; a housing forming a protective body about the element; electrical contacts integral to the housing and connecting to the strain element; and a buffer material ply (either stiff or soft compared to the base-structure) onto/into which the encapsulated power-generation transducer element is bonded (on at least one side) or coupled at one or both ends; these parts together form an assembly of selectable flexibility/stiffness. An optional electronic circuit board with electrical contacts to interface with the power generation elements and with the device to be powered may be integrated in the module.

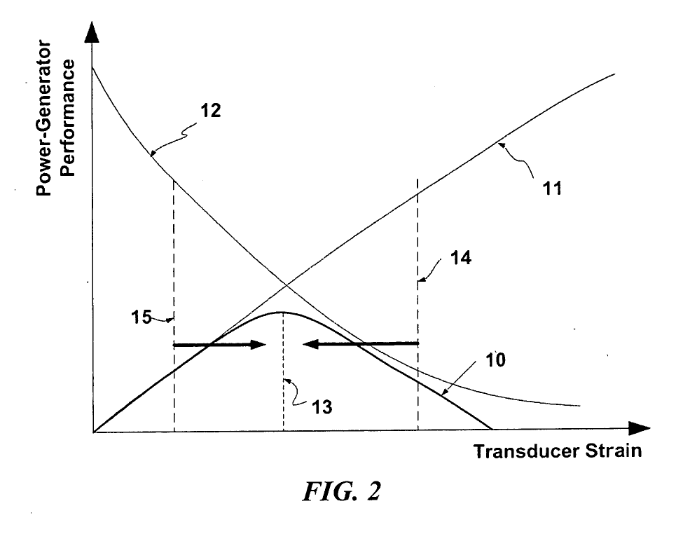

In general, there are transducer performance limits due to both mechanical strain input and integrity of the transducer. For a typical transducer element, the larger the input strain, the more power generation occurs. At the same time, the more the input strain, the more damage is accrued in the transducer element. An illustration of the general performance of an RPPGM module as a function of input strain is given in FIG. 2, where the overall performance 10 is determined by the combination of two limiting factors: limits due to mechanical input energy 11 and limits due to residual integrity of the transducer 12 as it is strained. The resulting overall performance may then be shown to have an optimal value 13 at a certain strain level. If mechanical input strains are too large, the transducer is operating in a regime where it is experiencing extreme damage 14, and overall performance is negatively affected. Conversely, if mechanical input strains are too small (compared to optimal), the transducer is under-utilized 15 and not all available energy is being generated for harvesting. A good design strives to center the operating regime around the optimal point 13, may be determined via a combination of analytical and experimental considerations, and is heavily dependent on the properties of the target base-structure.

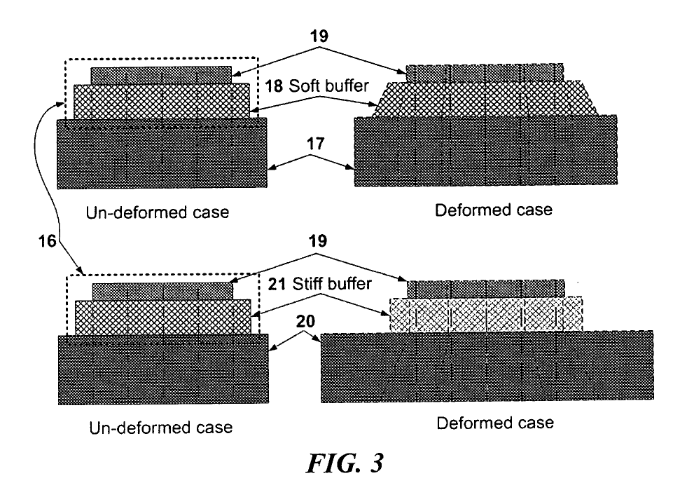

By introducing and integrating the buffer element between the base-structure and the transducer element, strains are restricted to levels that will not cause damage to the transducer but will enable it to perform at an optimal level. Problems may occur when potential structural strains are too large. Solutions to overstraining the transducer element are illustrated in FIG. 3, where the RPPGM module 16 connection to a base-structure can then either be made with a relatively soft 18 or relatively stiff 21 buffer ply.

For the case when motion is driven by a very stiff base-structure 17 (where strains are large enough to cause transducer element damage), a softer buffer material 18 (of stiffness lower than that of the base-structure) is appropriate. In this case the buffer element 18 absorbs most of the large strains and transfers the “optimal” strain level to the transducer 19. For the case when the base-structure 20 is relatively deformable and can cause large deflections by direct stretching or by inducing vibration/motion in the full or partially connected electro-active element, a ply of suitably sized buffer material 21 (relatively stiff compared to the base-structure) limits strains to acceptable levels in the transducer element 19. In this case the buffer element 21 restricts transferred strains to the transducer 19 by locally inhibiting deformation of the base-structure 20. Similarly, the module can be connected to a structure that can excite large deflections in the module (e.g., using a tip-mass on one end or by direct application) and the stiff buffer ply can be designed and sized to limit peak strains to acceptable levels for the power-generation transducer elements. In all cases, proper sizing of the buffer material enables optimal power extraction from the base-structure while maintaining high reliability and robustness.

Design of the buffer ply is not only dependent on material type but also on its geometry, namely its thickness (assuming platform area is determined). For the case when a stiff buffer ply is desired, increasing thickness for a certain buffer material increases stiffness. This consideration enables the use of lower cost materials when a thickness penalty can be tolerated in terms of integration with the base-structure. Conversely, if minimization of RPGM thickness is desired, there stiffer buffer materials are employed.

If on the other hand it is desired to have a relatively softer buffer ply that limits strain through its thickness (via shear-lag), increasing thickness will reduce strains experienced by the transducer.

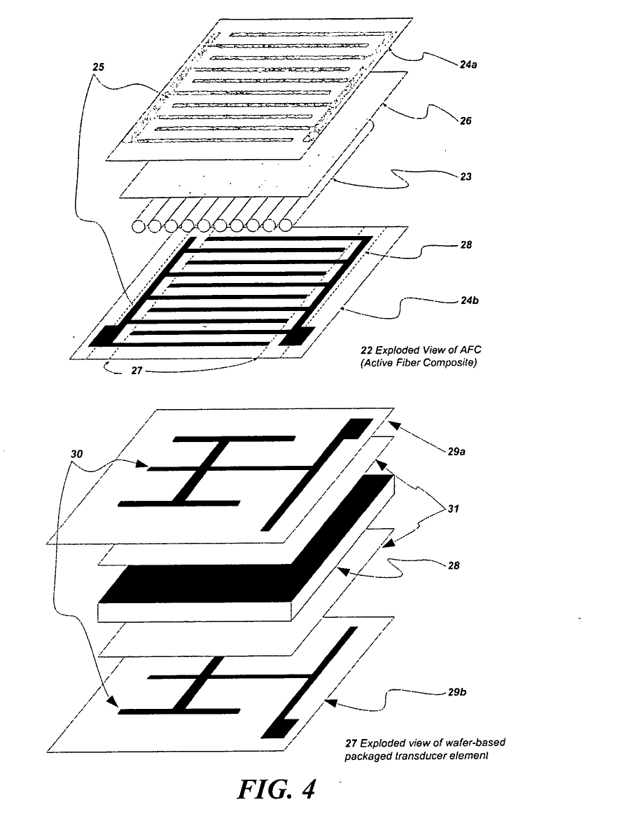

In a preferred embodiment, as illustrated in FIG. 4, the power-generation elements are Active Fiber Composite (AFC) piezoceramic plies 23 or piezoceramic plates/wafers 28 which are quite thin, preferably between slightly under an eighth of a millimeter to several millimeters thick, and which have a relatively large surface area compared to their cross-section, with one or both of their width and length dimensions being tens or thousands times greater than the thickness dimension. A metallized film with patterned electrode, a film with conductive ink electrode pattern, or a patterned conductive (metallic or ink) electrode directly onto the transducer is used to provide electrode contacts, while a structural epoxy and insulating material hermetically seal the device against delamination, cracking end environmental exposure. The electrodes may be generally referred to as an “electrically conductive pattern.”

In a preferred embodiment, the metallized film or conductive ink electrode and insulating material are both provided in a flexible circuit of tough polymer material and are attached or encapsulated on buffer composite plies, which thus provide suitable mechanical and electrical coupling to the enclosed elements.

By way of illustration, one example described below uses rectangular arrangements of lead zirconate titanate (PZT) transducer fibers a quarter millimeter thick, with length and width dimensions each of two to five centimeters, each element thus having an active power-generating face four to twenty-five square centimeters in area. The PZT fibers are encapsulated between sheets of a stiff strong polymer, such as thirteen, twenty-six or fifty-two microns thick polyamide or polyester, which has a suitable electrode pattern formed in the copper layer or in conductive ink on one side of one or both sheets for contacting the PZT fibers. The PZT fibers are arranged in a preform planar assembly and the entire structure is bonded together with a structural polymer into a waterproof, insulated closed package, having a thickness about the same as the fiber thickness, e.g. 0.300 to 0.350 millimeters.

So enclosed, the package may bend, extend and flex, and undergo sharp impacts, without fracturing the fragile PZT transducer fibers which are contained within. Further, because the conductor pattern is firmly attached to the polyimide or polyester sheet, even cracking of the PZT transducer element does not sever the electrodes, or prevent actuation or power-generation over the full area of the element, or otherwise significantly degrade its performance.

When exposed to very large strains (such as those caused by stretching rubber), however, the packaged device may still be subjected to damaging strains. For this reason the packaged active material is then bonded or encapsulated to one or two plies of buffer material (by way of example, for a case when rubber is the base-structure, then stiff fiberglass may be used) one half to one millimeter thick, via a thin layer of structural polymer, that act to reduce the strain transmitted from the structure to the encapsulated PZT transducer fibers. This packaged assembly can then be electrically connected via wires or flex-circuit to an optional energy-harvesting electronic circuit thus making a free-standing, independent energy-harvesting module.

In this module, the active element generates energy when strained. However, for most types of materials (e.g., piezoelectric, electrostrictive), there is a mechanical strain limit beyond which damage begins to occur. The buffer ply acts to safely limit the strain seen and also acts to uniformly distribute it to the active element. In order to accomplish this, the buffer ply must be stiffer than the local stiffiess of the base-structure it is being bonded to, or for the case when the module is not bonded but simply coupled, then the stiffness must act to restrict free-standing motion of the module to restrict the amount of damaging strain to the transducer element. In some cases, a very stiff structure can still induce potentially damaging strains into an integrated piezoelectric material so a soft buffer ply will act to limit strain. Key parameters of the buffer ply that can be changed are material type (rubber, foam, composite, plastic, metal) and geometry (most importantly thickness).

In general, it is assumed that the base-structure can impart damage to a plain, unprotected transducer material. If the base-structure undergoes very large deflections (approximately an order of magnitude larger than acceptable for the transducer), a relatively stiffer buffer ply is employed and properly sized to limit mechanical strains. If the base-structure undergoes moderately large deflections (on the order of mechanical limits for the transducer), a relatively softer buffer ply is employed to limit mechanical strains.

It is useful to design the entire system such that the active element is exposed to strains sufficient to produce the desired energy output that is processed by the harvesting electronics for the specific target application. When properly designed, this package successfully limits the amount of damaging strains that are experienced by the active element/ply while allowing it to generate a sufficient amount of energy to power devices. These options are well suited for use in displacement-driven applications where operational strains at the bond interface are greater than the allowable values for the active material.

The thin package may form a complete modular unit, in the form of a small “credit card” module, optionally complete with electrodes with integral electronics. The package may conveniently be attached by bonding one face to a structure or be simply connected or otherwise attached at one or both ends to the structure so that it transmits strain between the structure and the enclosed strain element. The bonding may be done, for example, by simply attaching the package with an adhesive to establish a thin, high shear strength connection with the transducer materials, while adding minimal mass to the system as a whole. The transducer material then responds to strain of the base-structure by generating surface charge that can be properly collected by the harvesting electronics.

In different embodiments, particular electrode patterns are selectively formed on the sheet or on the transducer to either pole the transducer plates, ribbons, fibers, or composites in-plane or cross-plane, and multiple layers of transducer elements may be arranged or stacked in a single card to result in increased energy generation.

In accordance with a further aspect of the invention, power-harvesting circuit elements are formed in, or with, the modular package to process the signal produced by the PZT elements.

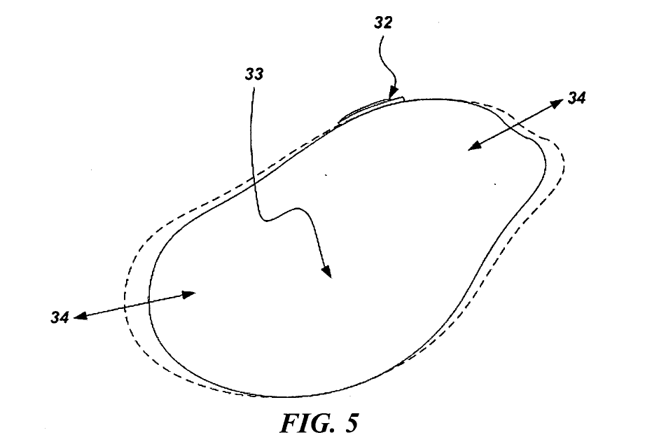

FIG. 5 shows a power generation module according to one embodiment of the present invention. As shown, it is a modular RPPGM pack 32 that simply attaches to a structure 33 that undergoes large deflections 34. A surface mount embodiment is illustrated; however, transducer modules may also be integrated into the base-structure). Attachment may be made with an adhesive (either quick setting or of the type employed for structural lamination and bonding), or, in other configurations, via a point or line. The operations of power generation or self-powering devices from a structure undergoing large deflection can benefit greatly from this architecture as the device may be readily installed and interfaced to electronics, if an embodiment in which the electronics are not integrated into the package. This package may incorporate energy-harvesting circuit elements so that the only external electrical connections necessary are two power leads, i.e. a source and a ground or return.

The present invention also pertains to piezoelectric composites, piezoelectric polymers, and materials, such as PZT, niobate crystal or similar piezoceramic materials. It also pertains to electrostrictive materials. As used in the claims below, both piezoelectric and electrostrictive elements, in which the material of the elements has an electromechanical property, are referred to as electro-active elements. This invention also contemplates the use of low-stiffness piezoelectric materials, such as polyvinylidene difluoride (PVDF) film and the substitution of lower cure temperature bonding or adhesive materials. Challenges for power-generation reliability and robustness, however, arise with all classes of transducer materials noted above, and these will now be described.

One embodiment of the present invention includes novel forms of generator elements and methods of making such generators, where “generator element” is understood to mean a complete and mechanically useful device which, when properly attached or connected to a structure, couples motion from the structure to electro-active element(s) associated with the generator element. In its broad form, the making of a generator involves “packaging” a raw transducer element to make it mechanically useful. By way of example, raw piezoelectric transducer materials or “elements” are commonly available in a variety of semi-processed bulk material forms, including raw piezoelectric material in basic shapes such as sheets, rings, washers, cylinders, fibers, plates as well as more complex or composite forms, such as stacks, or hybrid forms that include a bulk material with a mechanical element such as a lever. These materials or raw elements may have metal coated on one or more surfaces to act as electrical contacts, or may be non-metallized. In the discussion below, piezoelectric materials are discussed by way of example, and all these forms of raw materials are referred to as “elements”, “materials”, “electro-active elements”, or “transducer elements”.

Embodiments of the invention employ these electro-active materials in thin sheets, discs, annuli, plates, fibers, cylinders, or shells that are below several millimeters in thickness, and illustratively about one fifth to one quarter millimeter thick. Advantageously, this thin dimension allows the element to be attached to an object undergoing large deflections without greatly changing the structural or physical response characteristics of the object. However, in the prior art, such elements are fragile and may break due to irregular stresses when handled, assembled or cured. For instance, the impact from falling even a few centimeters may fracture a piezoceramic plate, and only extremely small bending deflections are tolerated before breaking.

In accordance with the present invention, the thin electro-active elements are encased by layers of thin insulating material, at least one of which is a tough film which has patterned conductors on one of its surfaces, and is thinner than the element itself. A package is assembled from the piezo elements, insulating layers, various spacers or structural fill material and buffer plies (either softer or stiffer than intended base-structure) on one or both sides such that altogether the electrodes, piezo element(s), enclosing films, and buffer outer plies form a sealed electro-active card.

The specifics of this assembly have been developed for use with Active Fiber Composite (AFC) materials however the general framework is suitable for use with other types of active material configurations. An exploded view of a typical AFC is shown in FIG. 4. The AFC material 22 employed in this application is an interdigitated electrode piezoelectric fiber composite, approximately 330 microns thick. The fibers 23 in the AFC are of PZT-5A piezoelectric material and are approximately 250 micron in diameter. The RPPGM module is incorporated into the structure such that the AFC fibers are lined up with the main strain direction. This preferential orientation guarantees maximal energy extraction. AFC longitudinal modulus (along fiber length) is 22-25 GPa. The encapsulating electrode material (24a for top and 24b for bottom side, where top and bottom are in reference to manufacturing position) is polyester or polyamide, typically in 13, 26, or 52 micron thickness that supports a screen-printed electrical pattern 25 with interdigital arrangement at a pitch of 1.143 mm.

The entire assembly is held together by a structural adhesive 26. The fibers 23 in the AFC are positioned such that they are only present in the active area 27. A standard AFC is 50 mm wide and 130 mm long. During assembly the top electrode is suitably trimmed 28 to leave the bottom tabs available for electrical connection.

A preferred method of manufacture involves applying pressure to the entire package as the adhesive 26 cures. Compression eliminates voids, provides a dense and crack-free solid medium, and creates thin bond layers for improved load/strain transfer, while the curing heat effects a high-degree of cross-linking, resulting in high strength and stiffness. The AFC 22 can sustain processing temperatures of up to 200° C., therefore, adhesives 26 that do not exceed this limit are acceptable for integration.

An optional transducer device similar to the AFC includes a packaged piezo-wafer assembly and is also shown in FIG. 4. The packaged piezo-wafer 27 is assembled with a process similar to that of an AFC and includes laminating a top 29a and bottom 29b electrode with suitable electrically conductive pattern 30 using adhesive 31.

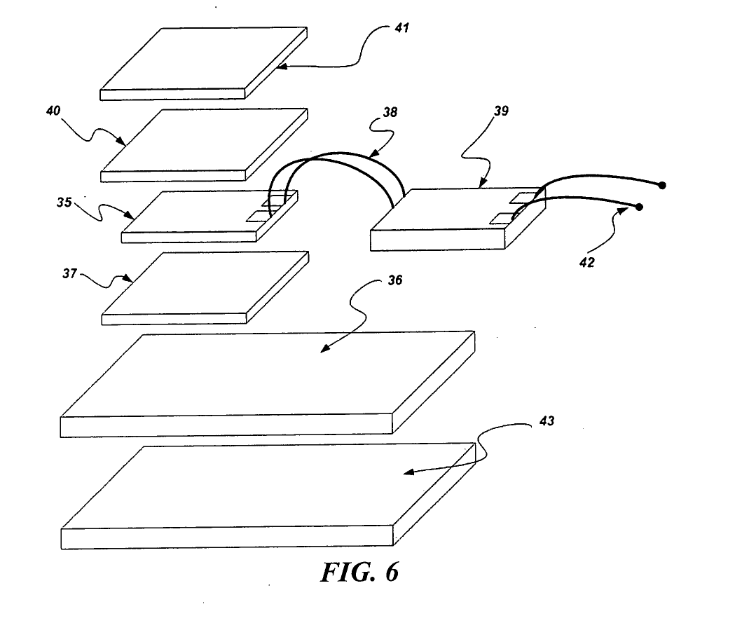

In one embodiment, shown in FIG. 6, the transducer element 35 is attached to the buffer ply 36 with a structural adhesive 37. Electrical connections 38 for the optional energy harvesting electronics 39 are available for connection via either flex-circuits or wires. The AFC 35 may be optionally encapsulated into the buffer ply 36 with another sheet of adhesive 40 and encapsulating cover sheet 41 made of polyester or polyimide material that is 50 micron thick.

The optional electronics module 39 has two output connections 42 that are available to power the load device. In functional form, the assembly “looks like” a standard transducer element, such as an AFC or piezo-wafer device, with electrical connections to the energy-harvesting electronics and bonded to the buffer ply 36, which is then bonded/attached to the surface of the base-structure 43. For the case of an AFC, bonding is done such that the active fibers are aligned with the direction of strain in the base-structure.

An alternative embodiment includes the AFC manufactured directly onto the buffer ply, thus eliminating the layer of encapsulating material present on one side between the piezoelectric fibers of the AFC and the stiff ply. In this case, electrical patterns and connections may be incorporated onto the stiff ply prior to assembly by printing a suitable conductive pattern with a conductive ink. In this case, the AFC is not a discrete component attached to the stiff ply.

By means of example, for the case of an AFC bonded directly to a thick rubber structure, and under the assumption that the stiffness of the structure is greater than the stiffness of the active element, the AFC experiences tensile strains approaching the peak values of the structure, in this case assumed to be on the order of 0.1-0.15%. The AFC is one of the most robust active elements and can tolerate longitudinal strains (aligned with piezoelectric fibers) as high as 0.02-0.03% before damage begins to occur and performance is affected. Therefore, attaching the AFC (and even worse for any other electro-active element) directly to the high-strain structure is not recommended as premature failure may occur. In this case, the introduction of a buffer material, namely a stiff fiberglass ply (locally stiffer than the structure) to reduce the peak strain transferred from the structure to the active element, provides a solution for a reliable and continuous operation. Calculations and experiments show that a 0.7 mm thick [0/90] fiberglass (or similar composite material) ply can successfully act to reduce mechanical strain on the active ply when the AFC is attached, for instance, to the thick rubber-based structure that undergoes large deflections. The ply also helps to reduce transmitted variations in strain, thus increasing power extraction effectiveness. Too large of a thickness works to cause too large of a strain on the AFC. Too small of a thickness causes the AFC to be overwhelmed by the structure's deflection, therefore allowing damage to develop in the AFC.

For the purpose of reliability, it is recommended that the stiff ply that interfaces with the structure have rounded edges. Further, electrical connections made between the AFC, the energy-harvesting electronics module, and the utility device may be encapsulated to prevent electrical interference and shorting.

In discussing the embodiments above, the direct transfer of motion from the base-structure to the electro-active material through the buffer ply and electrodes has been identified as a distinct advantage. Such operation is useful for energy-harvesting tasks for low profile assemblies where special intrusion must be minimized. However, while the electromechanical materials of these generators operate by strain energy conversion, applications of the present invention extend beyond strain-coupling through the generator surface, and include numerous specialized mechanical constructions in which the motion, torque or force coming from the structure as a whole is utilized.

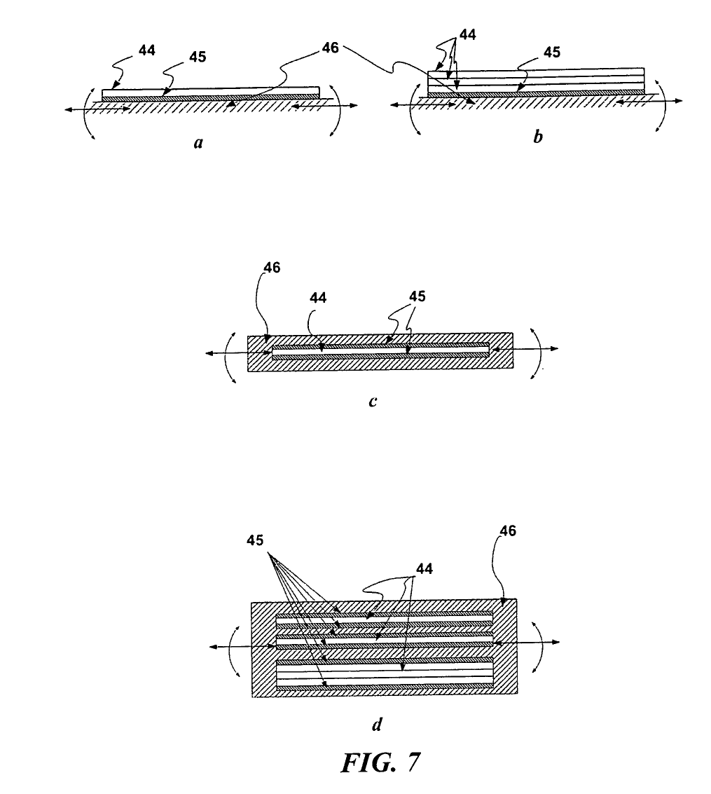

FIGS. 7a-7d are graphical representations of various example ways to connect the RPPGM module for energy extraction from a structure. The configuration of FIG. 7a is that of a surface-mounted transducer module 44 assembled to a single stiff buffer ply 45. This is intended for deployment of self-powered devices when intrusion on base-structure 46 behavior needs to be minimal. For the case when more power is needed, more electro-active elements 44 may be added to this same configuration, leading to that outlined in FIG. 7b. In both cases, the stiff buffer ply 45 acts to reduce the base-structure 46 motion transferred to the electro-active module. The module may also be fully integrated into a structure, in which case, the favored configuration is that outlined in FIG. 7c where the electro-active element 44 is encapsulated between two stiff buffer plies 45. Two buffer plies are used in this case to ensure that neither side of the electro-active transducer device 44 is exposed to large strains. For the case of bending, the transducer ply is located far enough from the neutral axis of the structure undergoing bending so that it is exposed to target strains.

FIG. 7d illustrates an implementation where multiple electro-active elements 44 and buffer layers 45 are stacked and encapsulated in a way that is embedded in the base-structure 46.

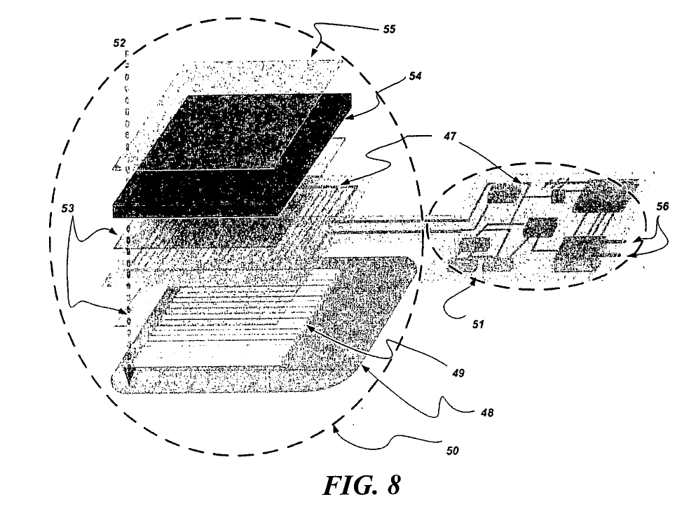

FIG. 8 illustrates an embodiment of the invention that integrates optional energy-harvesting electronics with an AFC-based electro-active transducer element. This design is intended to harvest energy from high strain motion of a base-structure and integrally provides energy to power load electronics. Some of the features of this design that lead to a low-cost, high performance product, include: (i) a special single sided electrode 47 with circuitry to both interface with the piezoelectric fibers (interdigital pattern) and employing surface mounting electronics, (ii) a buffer ply of suitable thickness fiberglass 48 to limit base-structure strains transferred to piezoelectric fibers 49, and (iii) compatibility with single “lamination” process 50. Most of the device, except for the optional surface mount electronics 51, can be assembled in one single step by stacking up components and applying pressure 52 and using adhesives 53. The surface mount electronics 51, with available electrical connections 56, can be integrated before or after the lamination step.

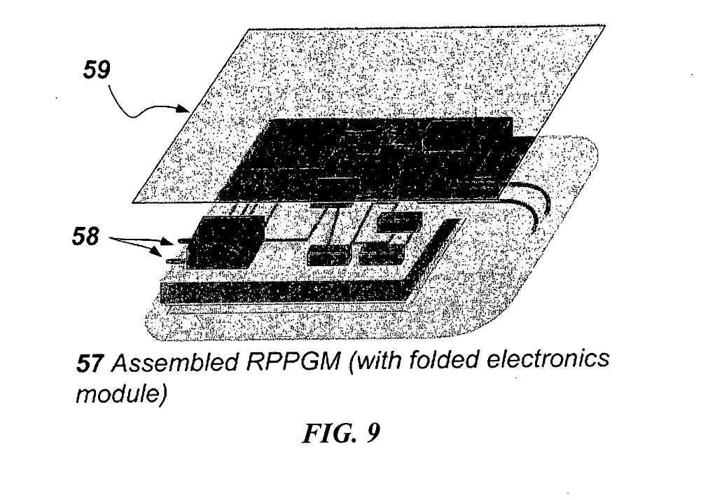

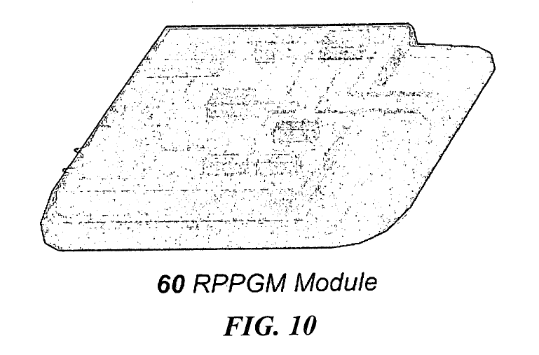

As illustrated in FIG. 9, once the components have been attached and bonded, the electronics module 51 can be flipped over onto the laminated stack, thus creating a compact, robust module 57 with two electrical connections 58 available to interface with load electronics. An encapsulating layer 59 is applied to the entire assembly to further hold and protect the components. The fully assembled and encapsulated module 60 is illustrated in FIG. 10.

In a further embodiment, the desired load electronics may be built and integrated into the energy-harvesting electronics 51 components (as described in reference to FIG. 8). The even more delicate electronics module 51 that has been folded over the laminated assembly is buffered from strain by the presence of additional buffer elements in the form of a mechanical isolation layer 54 and an additional (optional) stiff ply 55 (as described in reference to FIG. 8).

While this invention has been particularly shown and described with references to preferred embodiments thereof, it will be understood by those skilled in the art that various changes in form and details may be made therein without departing from the scope of the invention encompassed by the appended claims.

1. An electrical power generation system, comprising:
a transducer that generates electrical energy under dynamic mechanical loading; and
a buffer mechanically coupled to the transducer and adapted to be mechanically coupled to a structure, the buffer facilitating the transducer to operate within a predetermined mechanical loading range to allow the electrical power generation system to generate the electrical energy.

2. The system according to claim 1 wherein the buffer is stiffer than a local stiffness of the structure.

3. The system according to claim 2 wherein the buffer includes at least one of the following materials: composite, metal, fiber, or polymer.

4. The system according to claim 1 wherein the buffer is less stiff than a local stiffness of the structure.

5. The system according to claim 4 wherein the buffer includes at least one of the following materials: rubber, foam, plastic or composite.

6. The system according to claim 1 further including a second buffer coupled to the transducer separate from the other buffer.

7. The system according to claim 6 wherein the buffers form a seal around the transducer.

8. The system according to claim 1 further including an electrically conductive pattern electrically coupled to the transducer, the electrically conductive pattern collecting electrical energy generated by the transducer.

9. The system according to claim 8 wherein the system includes a second buffer encapsulating the transducer with the other buffer, the electrically conductive pattern including contacts exposed external from the buffers.

10. The system according to claim 8 wherein the electrically conductive pattern is disposed on a film in a layered relationship with the transducer.

11. The system according to claim 8 further including an energy harvesting circuit electrically coupled to the electrically conductive pattern and disposed in a layered relationship with the transducer.

12. The system according to claim 11 wherein the circuit and transducer are on the same layer.

13. The system according to claim 1 wherein the circuit and transducer are on different layers.

14. The system according to claim 1 wherein the buffer surrounds the transducer.

15. The system according to claim 1 wherein the transducer and buffer are in a layered relationship to each other.

16. The system according to claim 1 wherein the buffer is laminar.

17. The system according to claim 1 wherein the buffer is surface bonded to the structure.

18. The system according to claim 1 wherein the system is embedded in the structure.

19. The system according to claim 1 wherein the buffer defines at least two ends and at least one of the ends is attached to the structure.

20. The system according to claim 1 wherein the dynamic mechanical loading includes at least one of the following: strain, stress, or bending.

21. An electricity generator module, comprising:
a transducer that generates electrical energy under dynamic motion conditions;
a circuit coupled to the transducer that converts the electrical energy into usable electricity at a circuit output; and
a planar housing enclosing the transducer and circuit, the housing (i) allowing the transducer to be exposed to the dynamic motion conditions and (ii) providing electrical contacts coupled to the circuit output to facilitate delivery of the usable electricity for external circuitry.

22. The electricity generator module according to claim 21 wherein the housing includes a buffer coupled to the transducer that facilitates the transducer to experience the dynamic motion conditions and operate within a predefined range.

23. The electricity generator module according to claim 21 wherein the dynamic motion conditions include at least one of the following: strain, stress, and bending.

24. The electricity generator module according to claim 21 wherein the buffer is stiffer than a local stiffness of the source of the dynamic motion conditions.

25. The electricity generator module according to claim 21 wherein the buffer is softer than a local stiffness of the source of the dynamic motion conditions.

26. The electricity generator module according to claim 21 wherein the circuit is an energy harvesting circuit powered by the electrical energy generated by the transducer.

27. The electricity generator module according to claim 21 wherein the module is manufactured through a lamination process.

28. The electricity generator module according to claim 21 wherein the module is surface bonded to a structure.

29. The electricity generator module according to claim 21 wherein the module is attached to a structure.
